(19) United States
(12) Patent Application Publication
(10) Pub. No.: US 2026/0352091 A1
(43) Pub. Date: Nov. 5, 2026

(54) GATE DRIVE CIRCUIT FOR SEMICONDUCTOR SWITCHING ELEMENT, ELECTRIC MOTOR CONTROL SYSTEM, AND SEMICONDUCTOR DEVICE

(71) Applicant: Minebea Power Semiconductor Device Inc., Ibaraki (JP)

(72) Inventors: Hiroshi SUZUKI, Tokyo (JP); Tomoyuki MIYOSHI, Tokyo (JP); Tomoyasu FURUKAWA, Tokyo (JP)

(21) Appl. No.: 19/111,806

(22) PCT Filed: Apr. 11, 2023
(86) PCT No.: PCT/JP2023/014707

§ 371 Date: Mar. 14, 2025

(30) Foreign Application Priority Data
Sep. 16, 2022 (JP) 2022-148174

(51) Int. Cl. H02M 1/088; H02M 7/483; H02M 7/537; H03K 17/687; H10D 12/00

(52) U.S. Cl. CPC H02M 1/088; H02M 7/483; H02M 7/537; H03K 17/6871; H10D 12/441

(57) ABSTRACT

In a gate drive circuit for a semiconductor switching element whose drive is controlled by using two independent gate electrodes, a time constant of a gate electrode voltage in turning-off of a second gate electrode is set to be longer than that in turning-off of a first gate electrode, and a voltage V* of the second gate electrode at a time point at which maximum power is applied in turn-off of the semiconductor switching element satisfies Expression (1): Expression (1) 0≤V*≤predetermined value<+Vp (+Vp in the expression is a gate drive voltage in the case where the semiconductor switching element is on).

### TECHNICAL FIELD

The present invention relates to a gate drive circuit for a semiconductor switching element, an electric motor control system, and a semiconductor device.

### BACKGROUND ART

The market is steadily growing in electric vehicles (EV), power grids, and railways due to global trend for achieving a carbon-free society. In application in this market, there is used an electric power converter that outputs an AC current based on a DC power supplied from a DC power supply and drives an electric motor. As key components of the electric power converter, there are a semiconductor switching element and a gate drive circuit that drives the semiconductor switching element.

The semiconductor switching element requires to achieve low loss and withstanding capability so high that a large current flowing in the semiconductor switching element can be shut down without causing breakdown of the element. Moreover, there is a method of achieving high breakdown withstanding capability by a gate drive method or by using a circuit, in addition to achieving high breakdown withstanding capability of the semiconductor switching element itself. Various gate drive methods and drive circuits are studied to achieve such high breakdown withstanding capability.

Patent Literature 1 discloses a method of suppressing excessive voltage surge applied to a semiconductor switching element by performing soft shutdown of a gate when short-circuit occurs in a load.

Patent Literature 2 discloses an apparatus that detects an abnormal current or abnormal temperature in an operation and protects a semiconductor switching element.

### CITATION LIST

### Patent Literature

Patent Literature 1: JP2016-136819A Patent Literature 2: JPH06-125256A

### SUMMARY OF INVENTION

### Technical Problem

FIG. 22 of Patent Literature 1 describes a technique in which, when short-circuit occurs in a load in a dual-gate IGBT including a first gate electrode and a second gate electrode, charge accumulated in the second gate electrode is discharged via a second soft shutdown circuit (resistor R5+switch S5) with a slew rate of voltage increased.

However, there is such a problem that application of the above-mentioned technique is insufficient to derive an effect of improving shutdown withstanding capability of the semiconductor switching element (for example, dual-gate IGBT). Details are described later.

The present invention has been made to solve the above-mentioned problem, and an object is to provide a gate drive circuit for a semiconductor switching element, an electric motor control system, and a semiconductor device that can achieve high breakdown withstanding capability of the semiconductor switching element.

### Solution to Problem

In order to achieve the above-mentioned object, a gate drive circuit for a semiconductor switching element of the present invention is a gate drive circuit for a semiconductor switching element whose drive is controlled by using two independent gate electrodes, wherein a time constant of a gate electrode voltage in turning-off of a second gate electrode is set to be longer than that in turning-off of a first gate electrode, and a voltage V* of the second gate electrode at a time point at which maximum power is applied in turn-off of the semiconductor switching element satisfies Expression 1.

0≤V*≤predetermined value<+Vp Expression (1)

(+Vp in the expression is a gate drive voltage in the case where the semiconductor switching element is on)

Other modes of the present invention are explained in the embodiments described below.

### Advantageous Effects of Invention

The present invention can achieve high breakdown withstanding capability of a semiconductor switching element.

### BRIEF DESCRIPTION OF DRAWINGS

FIG. 1 is a diagram showing an entire configuration of an electric motor control system using an electric power converter according to a first embodiment.

FIG. 2 is a diagram showing a circuit of a gate drive device according to the first embodiment.

FIG. 3 is a diagram showing a drive method of a dual-gate IGBT in the case of normal off.

FIG. 4 is a diagram showing a drive method of the dual-gate IGBT in the case of simultaneous off.

FIG. 5 is a diagram showing a change of accumulated carriers in the dual-gate IGBT in the case of normal off.

FIG. 6 is a diagram showing a change of the accumulated carriers in the dual-gate IGBT in the case of simultaneous off.

FIG. 7 is a diagram showing a cause of a decrease in breakdown withstanding capability of the IGBT in the case of simultaneous off.

FIG. 8 is a diagram showing an example of a turn-off waveform according to the present embodiment in the case of simultaneous off.

FIG. 9 is a diagram showing an example of a turn-off waveform in a comparative example in the case of simultaneous off.

FIG. 10 is a diagram showing a boosting mechanism of a gate voltage of a second gate electrode according to the first embodiment.

FIG. 11 is a diagram showing a circuit of a gate drive device according to a second embodiment.

FIG. 12 is a diagram showing a gate voltage command in the case of simultaneous H according to the second embodiment.

FIG. 13 is a diagram showing the gate voltage command in the case of normal off according to the second embodiment.

FIG. 14 is a diagram showing an example (modified example 1) of the semiconductor switching element.

FIG. 15 is a diagram showing an example (modified example 2) of the semiconductor switching element.

### DESCRIPTION OF EMBODIMENTS

Modes for carrying out the present invention (hereinafter, referred to as “embodiments”) are explained below with reference to the drawings as appropriate.

### First Embodiment

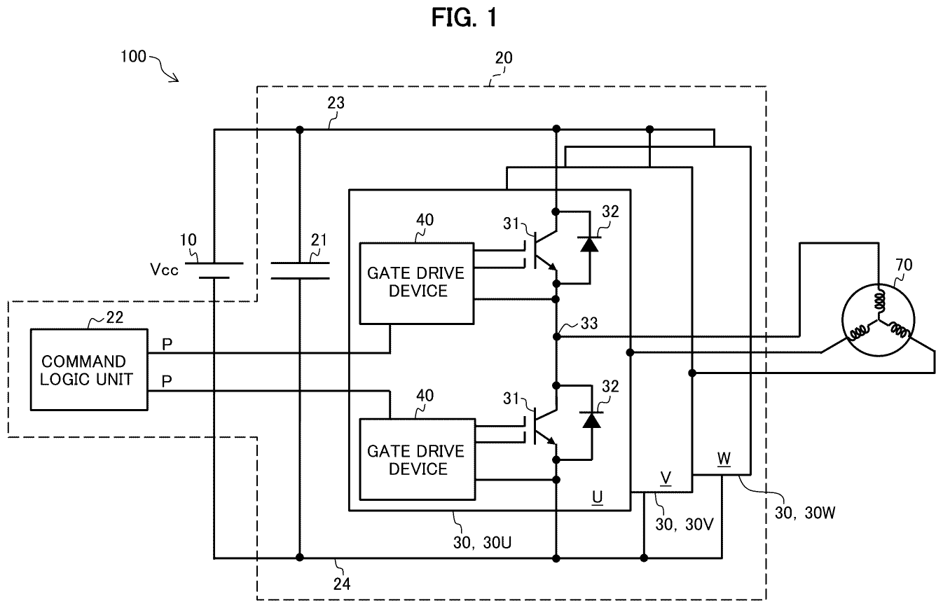

FIG. 1 is a diagram showing an entire configuration of an electric motor control system 100 using an electric power converter according to a first embodiment. The electric power converter is a device that converts power by using a power semiconductor device. In this example, the electric motor control system 100 using an inverter circuit is explained.

The electric motor control system 100 is formed of a DC power supply 10, an inverter circuit 20, an electric motor 70, and the like. The inverter circuit 20 includes smoothing capacitor 21, inverter units 30 for three phases of U, V, and W phases (U-phase inverter unit 30U, V-phase inverter unit 30V, and W-phase inverter unit 30W), and a command logic unit 22. The inverter circuit 20 outputs an AC power based on a DC power supplied from the DC power supply, and drives the electric motor 70. The smoothing capacitor 21 is provided between a positive electrode connection line 23 and a negative electrode connection line 24 of the DC power supply 10 (power supply voltage=Vcc) and the inverter circuit 20.

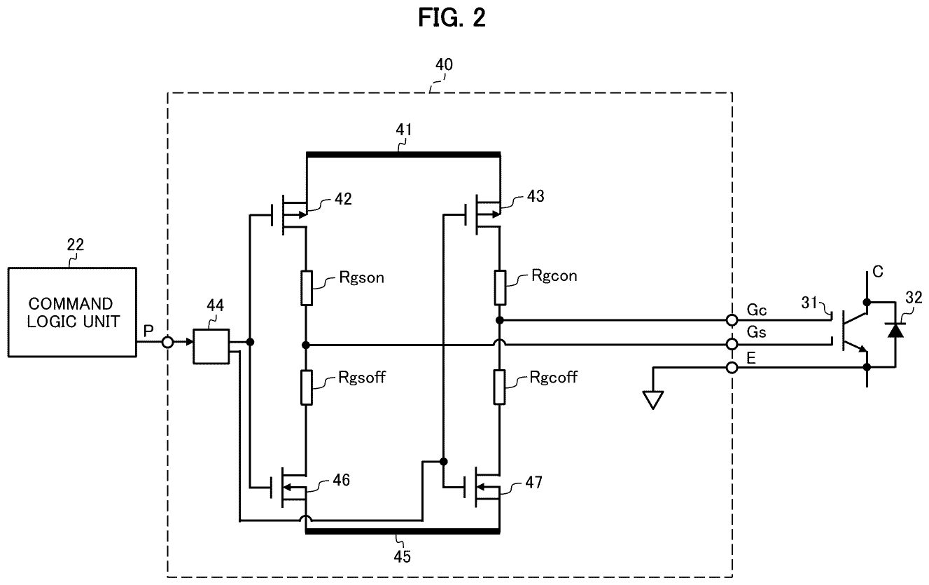

Each of the inverter units 30 is formed of upper and lower arms, and includes a series circuit of semiconductor switching elements 31. The semiconductor switching element 31 for each of the upper and lower arms is formed of a dual-gate IGBT (hereinafter, referred to as IGBT in some cases). A gate signal is transmitted from a gate drive device 40 to the dual-gate IGBT. A high-potential side terminal of the IGBT in the upper arm is connected to a first end (positive electrode connection line 23) of the smoothing capacitor 21. A lower-potential side terminal of the IGBT in the upper arm is connected to a high-potential side terminal of the IGBT in the lower arm. A lower-potential side terminal of the IGBT in the lower arm is connected to a second end (negative electrode connection line 24) of the smoothing capacitor 21. Note that the dual-gate IGBT is described later with reference to FIGS. 2 to 6. In this description, IGBT is an abbreviation of insulated gate bipolar transistor.

In each phase, a connection point 33 between the low-potential side terminal of the IGBT in the upper arm and the high-potential side terminal of the IGBT in the lower arm is connected to one end of a coil in the electric motor 70. The other end of the coil of each phase is connected to a neutral point. The electric motor 70 is, for example, an induction motor.

A free-wheeling diode 32 is connected to each IGBT in inverse parallel. Various types of diodes such as a pn junction diode, a Schottky barrier diode, and a diode using both of a pn junction and a Schottky junction may be used as the free-wheeling diode 32.

The command logic unit 22 outputs an on command instructing an on state or an off command instructing an off state to the gate drive devices 40 as drive command signals P for the semiconductor switching elements 31. The command logic unit 22 thereby alternately sets the semiconductor switching element 31 of the upper arm and the semiconductor switching element 31 of the lower arm in each phase to the on state to control a control amount of the electric motor 70 to a command value of the electric motor 70. The control amount is, for example, a torque of the electric motor.

The gate drive devices 40 are provided to correspond to the respective semiconductor switching elements 31, and obtain the drive command signals P from the command logic unit 22 to set the semiconductor switching elements 31 to the on state or the off state based on the obtained drive command signals P.

FIG. 2 is a diagram showing a circuit of the gate drive device 40 according to the first embodiment. FIG. 2 shows the semiconductor switching element 31 relating to the lower arm of the U phase and the gate drive device 40 of this semiconductor switching element 31 in the inverter circuit 20 shown in FIG. 1. Moreover, the semiconductor switching elements and the gate drive devices of these semiconductor switching elements in the upper arm of the U phase and the upper and lower arms of the V phase and the W phase also have the same configurations.

Although configurations and operations of the semiconductor switching element 31 in the lower arm of the U phase and the gate drive device 40 of this semiconductor switching element 31 are explained below, configurations and operations of the other semiconductor switching elements and the gate drive devices of these semiconductor switching elements are also the same.

The gate drive device 40 is configured to include a positive-side power supply 41, a first PMOSFET 42, a second PMOSFET 43, on-side gate resistances Rgcon and Rgson, a delay controller 44, a negative-side power supply 45, off-side gate resistances Racoff and Rgsoff, a first NMOSFET 46, and a second NMOSFET 47. In this example, PMOSFET is P-type metal-oxide-semiconductor field-effect transistor, and NMOSFET is N-type metal-oxide-semiconductor field-effect transistor.

An output part of the gate drive device 40 is connected to a first gate electrode Gs and a second gate electrode Gc of the semiconductor switching element 31. A reference potential of the gate drive device 40 is connected to an emitter terminal E of the semiconductor switching element 31.

Moreover, the command logic unit 22 is connected to an input part of the gate drive device 40. A source of the first PMOSFET 42 is connected to the positive-side power supply 41. A drain of the first PMOSFET 42 is connected to one end of the on-side gate resistance Rgson, and a drain of the first NMOSFET 46 is connected to one end of the off-side gate resistance Rgsoff. The other end of the on-side gate resistance Rgson and the other end of the off-side gate resistance Rgsoff are both connected to the output part of the gate drive device 40. A source of the first NMOSFET 46 is connected to the negative-side power supply 45. A gate of the first PMOSFET 42 and a gate of the first NMOSFET 46 are both connected to an output part of the delay controller 44.

Similarly, a source of the second PMOSFET 43 is connected to the positive-side power supply 41. A drain of the second PMOSFET 43 is connected to one end of the on-side gate resistance Rgcon, and a drain of the second NMOSFET 47 is connected to one end of the off-side gate resistance Rgcoff. The other end of the on-side gate resistance Rgcon and the other end of the off-side gate resistance Rgcoff are both connected to the output part of the gate drive device 40. A source of the second NMOSFET 47 is connected to the negative-side power supply 45. A gate of the second PMOSFET 43 and a gate of the second NMOSFET 47 are both connected to the output part of the delay controller 44.

### [Explanation of Operation]

The drive command signal P is inputted from the command logic unit 22 into the gate drive device 40. The gate drive device 40 causes the delay controller to operate such that the PMOSFETs are turned on and the NMOSFETs are turned off while the drive command signal P is inputted. The gate drive device 40 thereby causes a current (gate current) to flow from the positive-side power supply 41 toward the first and second gates of the semiconductor switching element 31 via the on-side gate resistances. In this case, a gate-emitter capacitance of the semiconductor switching element 31 is charged, a voltage (for example, Vp=+15 V) exceeding a threshold voltage of the semiconductor switching element 31 is applied, and the gate drive device 40 turns on the semiconductor switching element 31 and causes a current to flow in the semiconductor switching element (turn-on). The switching speed of the turn-on is controlled by adjusting the resistance values of the on-side gate resistances Rgcon and Rgson.

Normally, in the turn-on, the first and second gate electrodes are simultaneously turned on. Specifically, in the turn-on, a time difference set in the delay controller 44 is set to zero. However, a delay may be provided.

Moreover, the gate drive device 40 causes the delay controller to operate such that the PMOSFETS are turned off and the NMOSFETS are turned on while no drive command signal P is inputted from the command logic unit 22. This causes the gate current to flow from a gate of the semiconductor switching element 31 toward the negative-side power supply via the off-side gate resistances. In this case, the gate-emitter capacitance of the semiconductor switching element 31 is discharged, a voltage (for example, −Vm=−15 V) lower than the threshold voltage of the semiconductor switching element is applied, and the semiconductor switching element 31 is turned off to cut off the current of the semiconductor switching element 31 (turn-off). The switching speed of the turn-off is controlled by adjusting the resistance values of the off-side gate resistances Rgcoff and Rgsoff.

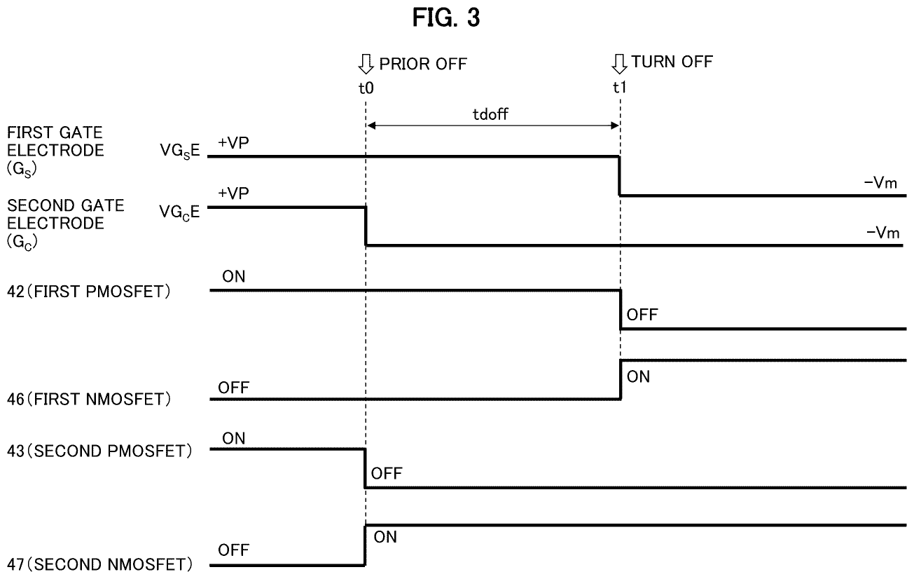

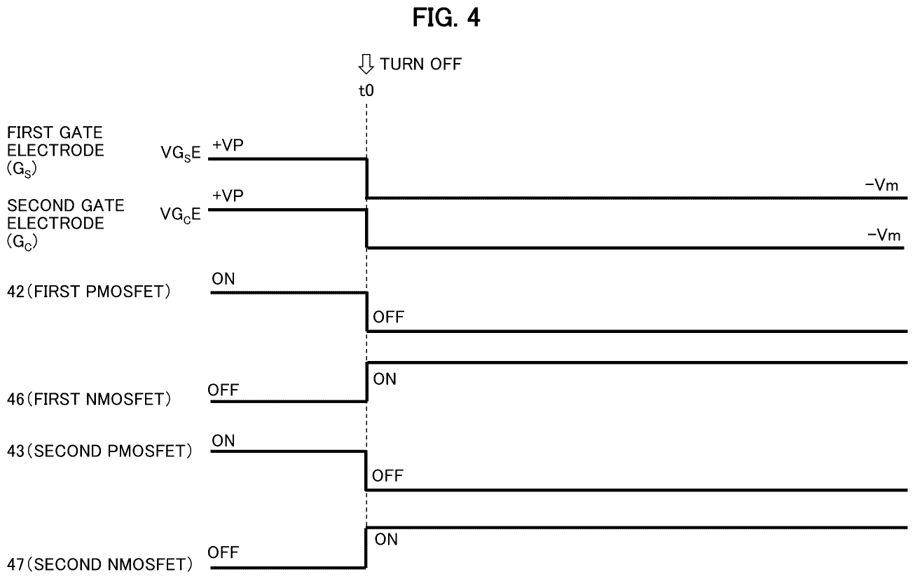

Normally, in the turn-off, the second gate electrode Gc is turned off prior to the first gate electrode Gs. Specifically, in the turn-off, the time difference set in the delay controller 44 is set to tdoff (20). In a situation where emergency shutdown of all gates is performed due to a system error or the like, the delay may be set to zero (tdoff≈0). Details are described later in FIGS. 3 and 4.

A relationship between the voltages of the gate electrodes and the switching of the MOSFETs in the turn-off is explained.

FIG. 3 is a diagram showing a drive method of the dual-gate IGBT in the case of normal off (in the case where the second gate electrode Gc is turned off prior to the first gate electrode Gs). In the turn-off of the second gate electrode Gc, the second PMOSFET 43 is turned off, and the second NMOSFET 47 is turned on. Then, in the turn-off of the first gate electrode Gs after tdoff, the first PMOSFET 42 is turned off, and the first NMOSFET 46 is turned on.

FIG. 4 is a diagram showing a drive method of the dual-gate IGBT in the case of simultaneous off (in the case where the second gate electrode Gc and the first gate electrode Gs are simultaneously turned off). In the turn-off of the second gate electrode Gc, the second PMOSFET 43 is turned off, and the second NMOSFET 47 is turned on. Simultaneously, in the turn-off of the first gate electrode Gs, the first PMOSFET 42 is turned off, and the first NMOSFET 46 is turned on.

### [Detailed Explanation of Problems in Achieving High Shutdown Withstanding Capability]

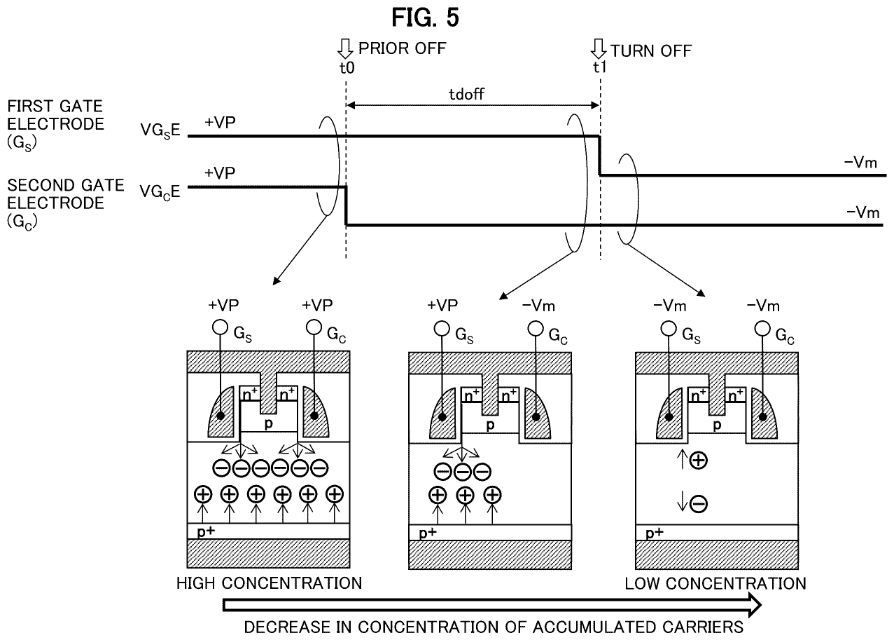

FIG. 5 is a diagram showing a change of accumulated carries in the dual-gate IGBT in the case of normal off. As shown in FIG. 5, the dual-gate IGBT includes the first gate electrode Gs and the second gate electrode Gc, and controls accumulated carries in the IGBT by using two gate electrodes of the first gate electrode Gs and the second gate electrode Gc. As described above, the second gate electrode Gc is set to the off state prior to the first gate electrode Gs, immediately before the turn-off of the IGBT (t=t0). After the prior turn-off of the second gate electrode Gc, supply of electrons from the gate of the second gate electrode Gc stops. Accordingly, as shown in FIG. 5, the accumulated carries (=minority carriers, holes) in the IGBT decrease over time according to the lifetime of the carriers.

When a certain time elapses from the prior turn-off of the second gate electrode Go and then the first gate electrode Gs is set to the off state, the IGBT is turned off (t=t1). After elapse of tdoff, the concentration of the accumulated carriers in the IGBT is sufficiently low, and turn-off loss is thereby reduced. However, depending on a control mode of the IGBT, the IGBT needs to be turned off in sufficiently short tdoff or tdoff≈0. A situation where emergency shutdown of all gates is performed due to a system error or the like can be given as an example.

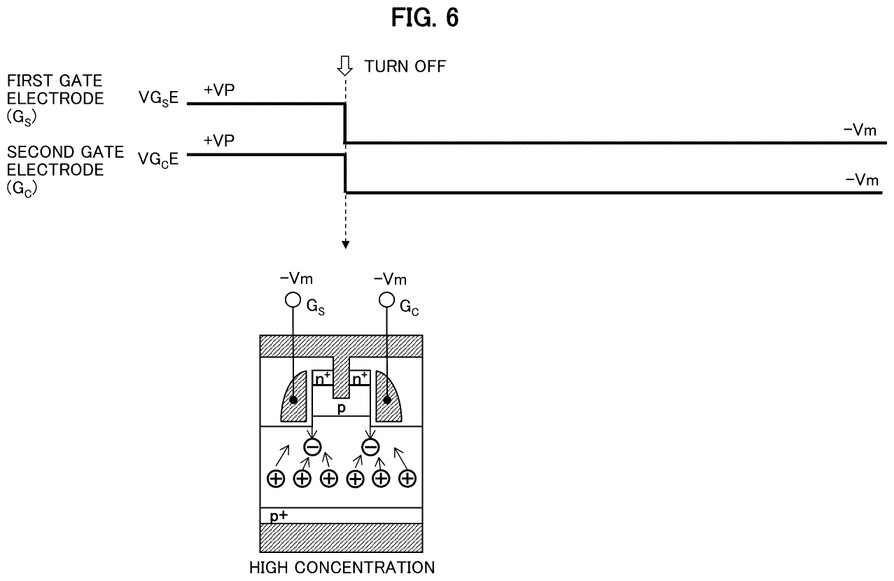

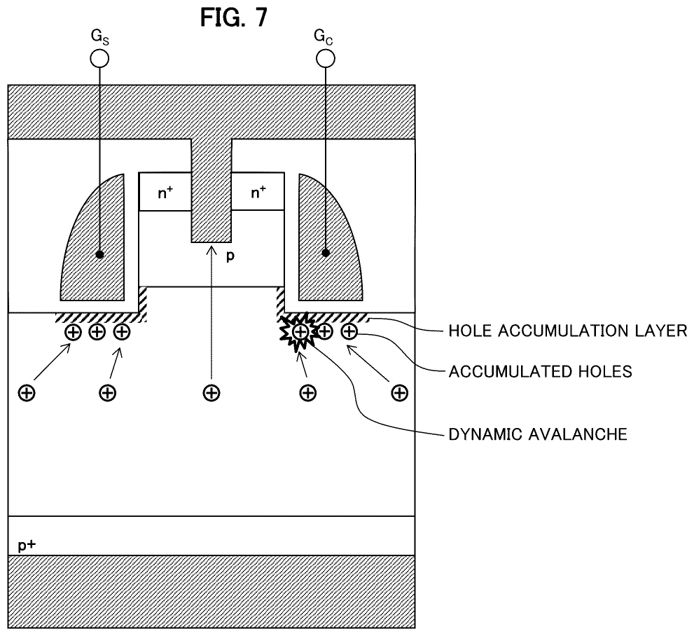

FIG. 6 is a diagram showing a change of the accumulated carriers in the dual-gate IGBT in the case of simultaneous off. FIG. 7 is a diagram showing a cause of a decrease in breakdown withstanding capability of the IGBT in the case of simultaneous off. In the case of FIG. 6, the IGBT is turned off in a state where the concentration of the accumulated carriers in the IGBT is high. In the case where the shutdown is performed in a state where a gate of the second gate electrode Gc is negatively biased, as shown in FIG. 7, a hole accumulation layer is formed under the gate. In this case, the current flowing in the IGBT concentrates in a region where this hole accumulation layer is formed. Accordingly, the electric field intensity in this region increases, dynamic avalanche is induced, and a generated avalanche current causes latch-up breakdown of the IGBT. In other words, there is a problem of a decrease in IGBT breakdown withstanding capability.

### [Improvement Method]

The present embodiment provides a method for improving the above-mentioned problem of the decrease in the breakdown withstanding capability of the IGBT that occurs with the formation of the hole accumulation layer under the gate.

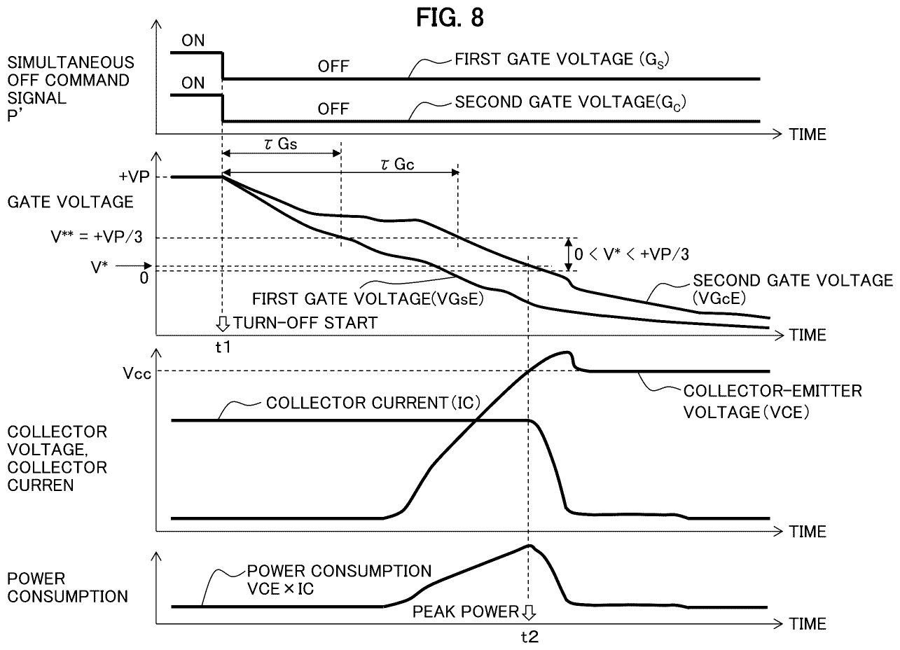

FIG. 8 is a diagram showing an example of a turn-off waveform according to the present embodiment in the case of simultaneous off. As shown in FIG. 8, in the present embodiment, the off-side gate resistance Rgcoff of the second gate electrode Gc in FIG. 2 is adjusted such that a time constant τGc in the turning-off of the second gate electrode Gc is longer than a time constant tGs in the turning-off of the first gate electrode Gs. In this case, the time constant tGs is defined by a time difference from a time point t1 of start of the turn-off of the first gate electrode Gs to a time point at which a gate voltage (VGsE) of the first gate electrode Gs reaches ⅓ (+VP/3) of a positive-side power supply voltage of the gate drive device (the time constant τGc is also defined in the same manner). Note that the time constant in the turning-off of the first gate electrode Gs means a time constant after the off command of the first gate electrode Gs. The same applies also to the time constant in the turning-off of the second gate electrode Gc.

Moreover, FIG. 8 shows the case where the IGBT is turned off in a state where tdoff=0 and the concentration of the accumulated carriers in the IGBT is high, that is the case where the IGBT shutdown withstanding capability is lowest. As shown in FIG. 8, in the present embodiment, the off-side gate resistance Rgcoff of the second gate electrode Gc in FIG. 3 is adjusted such that a voltage VGcE of the second gate electrode is higher than 0 V and is lower than +VP/3 at a time point at which the power consumption of the switching element is highest in the turn-off, that is a time point (peak power in FIG. 8: t2) at which a collector-emitter voltage VCE becomes substantially equal to the power supply voltage Vcc. Adjusting the off-side gate resistance Rgcoff can adjust the voltage VGcE of the second gate electrode.

Specifically, the gate drive circuit of the dual-gate IGBT (semiconductor switching element) is characterized in that, in the gate drive circuit for the semiconductor switching element whose drive is controlled by using the two independent gate electrodes, the time constant of the gate electrode voltage in the turning-off of the second gate electrode Gc is set to be longer than that in the turning-off of the first gate electrode Gs, and the voltage V* of the second gate electrode Gc at the time point at which the maximum power is applied in the turn-off of the dual-gate IGBT satisfies Expression (1).

0≤V*≤predetermined value<+Vp Expression (1)

(+Vp in the expression is a gate drive voltage in the case where the semiconductor switching element is on)

The predetermined value is the threshold voltage Vth of the semiconductor switching element. Specifically, the predetermined value is preferably +Vp/2. Moreover, as described above, the predetermined value is more preferably +Vp/3.

When V* is negatively biased (V*<0 V), as shown in FIG. 7, the hole accumulation layer is formed under each gate. In this case, the current flowing in the IGBT concentrates in the region where this hole accumulation layer is formed. Accordingly, the electric field intensity in this region increases, the dynamic avalanche is induced, and the generated avalanche current causes latch-up breakdown of the IGBT. In other words, the IGBT breakdown withstanding capability decreases. Accordingly, 9SV* is desirable from the viewpoint of achieving high breakdown withstanding capability.

For example, when V* is set higher than +VP/3 (V*>+VP/3), generally, in many voltage control type semiconductor switching elements (for example, IGBT), V* exceeds the threshold voltage (Vth). Accordingly, time taken for an electronic channel of the IGBT to become off in the turn-off becomes long, and the switching loss (turn-off loss) sharply increases. Thus, V*≤+VP/3 is more preferable from the viewpoint of reducing loss.

Accordingly, the gate voltage of the second gate electrode Gc is controlled to be in a range of 0≤V*≤+VP/3 at the time point at which the power consumption of the switching element is highest (at the time point at which the maximum power is applied) in the turn-off, and the hole accumulation layer under the gate as shown in FIG. 7 is thus not formed. Hence, the dynamic avalanche is less likely to occur in this region, the latch-up breakdown of the IGBT is prevented, and the breakdown withstanding capability of the IGBT is improved.

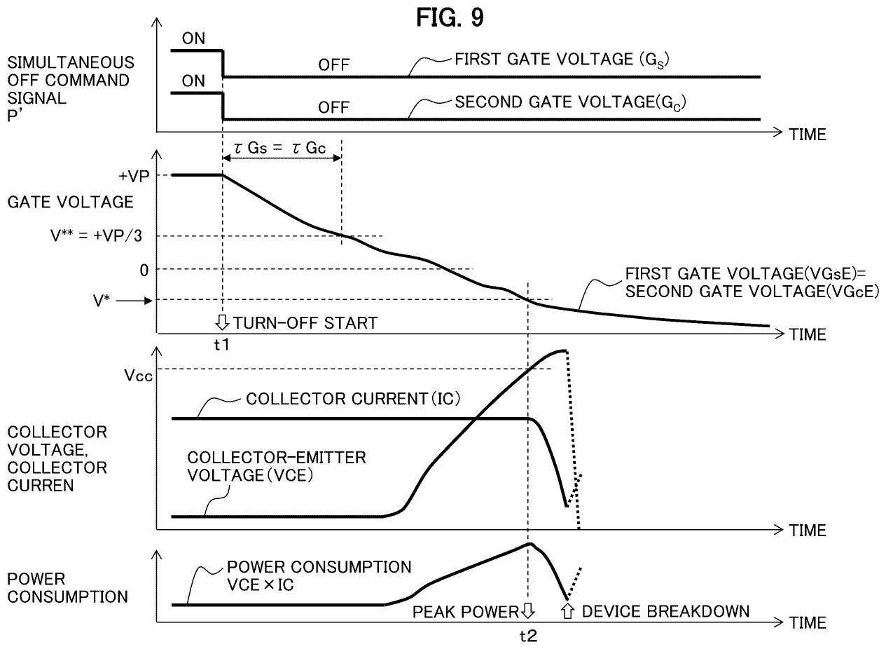

FIG. 9 is a diagram showing an example of a turn-off waveform in a comparative example in the case of simultaneous off. As a reference, FIG. 9 is a case where time constant TGS=τGc as a comparative example. In some cases, the semiconductor switching element that is the device exceeds an insulation withstanding capability after a time point t2, and breaks.

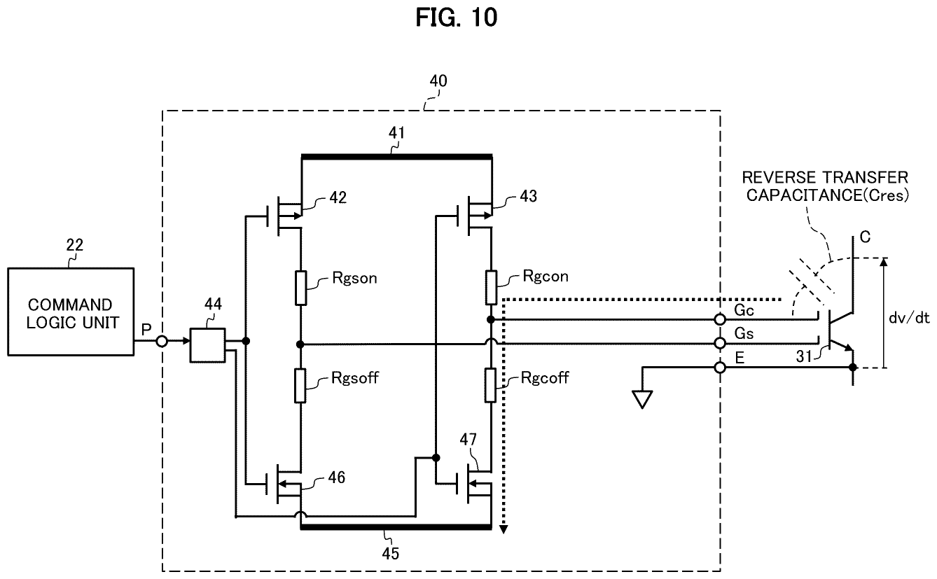

FIG. 10 is a diagram showing a boosting mechanism of the gate voltage of the second gate electrode Gc according to the first embodiment. As shown in FIG. 10, when the collector-emitter voltage VCE increases in the turn-off (when dv/dt is applied), a current (Cres×dv/dt) via a collector-gate reverse transfer capacitance Cres flows in via the off-side gate resistance Rgcoff. Accordingly, a voltage drop in the off-side gate resistance Rgcoff is increased (controlled) by increasing (adjusting) the off-side gate resistance Rgcoff of the second gate electrode Gc in FIG. 10, and as a result, the voltage VGcE of the second gate electrode can be adjusted to be higher than 0 V and lower than +VP/3 at the time point of peak power (t2) in FIG. 8. This can achieve high breakdown withstanding capability of the semiconductor switching element 31.

### Second Embodiment

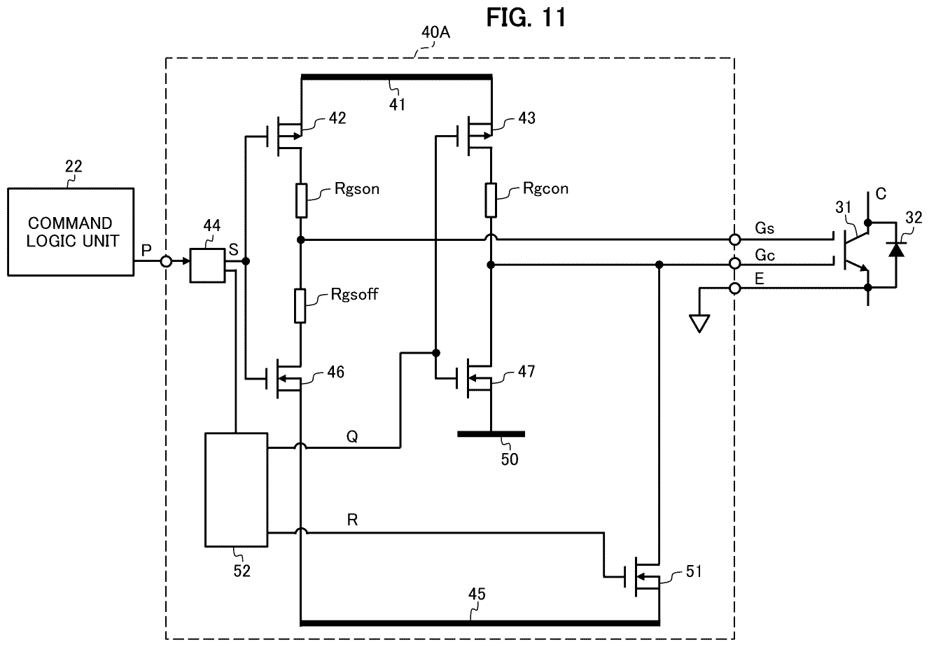

FIG. 11 is a diagram showing a circuit of a gate drive device 40A according to a second embodiment. A difference from the first embodiment is that, instead of controlling the time constant τGc in the turning-off of the second gate electrode Gc with the off-side gate resistance Rgcoff of the second gate electrode Gc, the voltage VGcE of the second gate electrode Gc is turned off in two stages in the turn-off of the semiconductor switching element 31 by using an intermediate power supply 50 (power supply voltage=V**)

A difference of a circuit (see FIG. 11) of the gate drive device 40A in the second embodiment to the circuit (see FIG. 2) of the gate drive device 40 in the first embodiment in terms of configuration is that the intermediate power supply 50, a third NMOSFET 51 (gate switch), and a switch controller 52 are provided instead of the off-side gate resistance Rgcoff of the second gate electrode Gc.

The source of the second NMOSFET 47 is connected to the intermediate power supply 50, the drain of the second NMOSFET 47 is connected to the output part (second gate electrode Gc) of the gate drive device, and the gate of the second NMOSFET 47 is connected to an output of a command signal Q of the switch controller 52. A source of the third NMOSFET 51 is connected to the negative-side power supply, a drain of the third NMOSFET 51 is connected to the output part (second gate electrode Gc) of the gate drive device, and a gate of the third NMOSFET 51 is connected to an output of a command signal R of the switch controller 52. An input of the switch controller 52 is connected to the output of the delay controller 44. Other connection modes and configurations are the same as those in the circuit of the gate drive device 40 (see FIG. 2) in the first embodiment.

### [Explanation of Operation]

Since operations other than the operation of turn-off are the same as those in the first embodiment, explanation is given while focusing on explanation of the operation of turn-off.

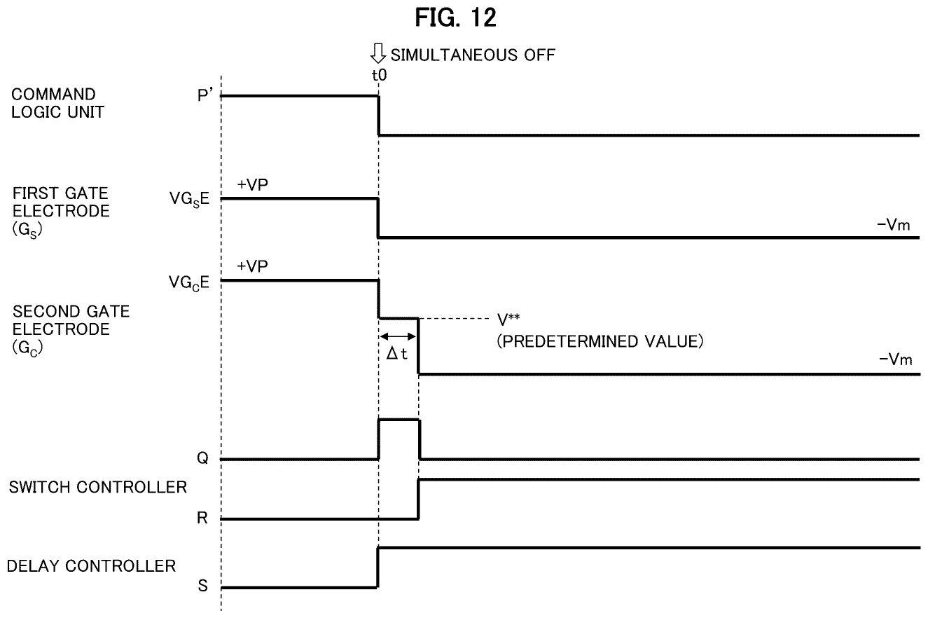

FIG. 12 is a diagram showing a gate voltage command in the case of simultaneous off according to the second embodiment. FIG. 12 shows a case where a simultaneous off command signal (P') is transmitted instead of the drive command signal (P) from the command logic unit 22 to the delay controller 44, for example, in a situation where the emergency shutdown of all gates is performed due to a system error or the like.

As shown in FIG. 12, the delay controller 44 transmits the command signal (not shown) to the switch controller 52 at a time point to at which the drive command signal (P′) transmitted from the command logic unit 22 to the delay controller 44 becomes an off command.

Then, the switch controller 52 transmits the command signal Q for a predetermined time At defined in advance, and sets the second PMOSFET 43 to off from this point on while setting the second NMOSFET 47 to on for the predetermined time At to reduce the voltage VGcE of the second gate electrode Gc to V** that is an intermediate voltage. Moreover, the switch controller 52 transmits the command signal R after elapse of the predetermined time Δt, and after the turn-off of the second NMOSFET 47, sets the third NMOSFET 51 to on from this point on to reduce the voltage VGcE of the second gate electrode Gc to the negative-side power supply voltage (−Vm) of the gate drive device 40A.

After reception of the simultaneous off command signal (P′), the delay controller 44 transmits the command signal S without delay (tdoff=0), sets the first PMOSFET 42 to off from this point on while setting the first NMOSFET 46 to on to turn off the first gate electrode Gs, and turns off the semiconductor switching element.

In this case, since the first gate electrode Gs and the second gate electrode Gc are substantially simultaneously turned off, the turn-off waveform shown in FIG. 8 is obtained. Thus, as in the operation in the first embodiment, the voltage VGcE of the second gate electrode Gc can be controlled to be higher than 0 V and lower than +VP/3 at the time point at which the power consumption of the switching element is highest in the turn-off, that is at the time point (peak power of FIG. 8: t2) at which the collector-emitter voltage VCE becomes substantially equal to the power supply voltage Vcc.

Accordingly, since the gate voltage of the second gate electrode Gc is controlled to be within the range of 0≤V*≤+VP/3 at the time point at which the power consumption of the switching element is highest in the turn-off, no hole accumulation layer under the gate as shown in FIG. 7 is formed. Thus, dynamic avalanche is less likely to occur in this region, the latch-up breakdown of the IGBT is prevented, and the breakdown withstanding capability of the IGBT is improved.

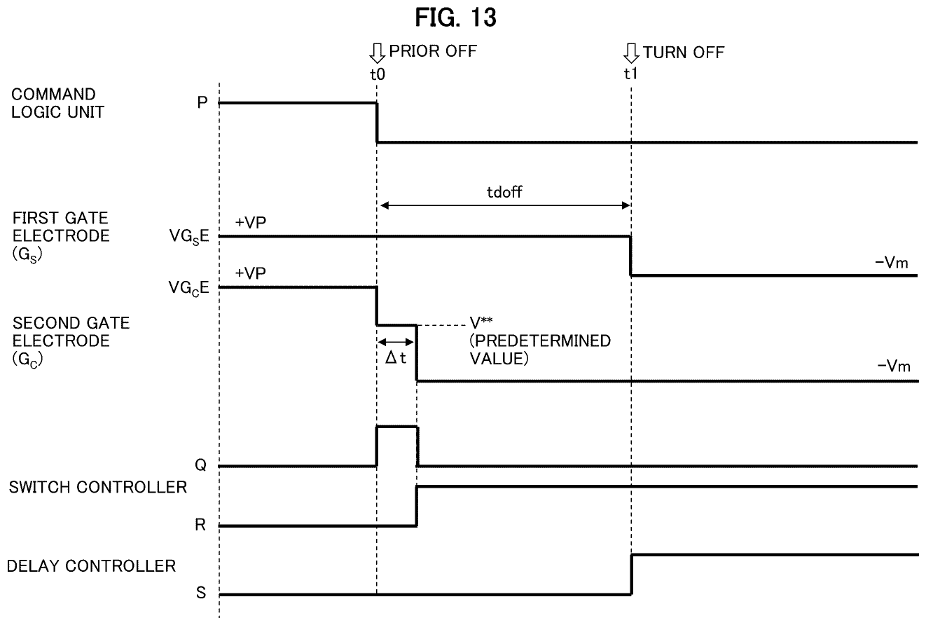

FIG. 13 is a diagram showing the gate voltage command in the case of normal off according to the second embodiment. The operation of the switch controller 52 is the same as that in FIG. 12. The delay controller 44 receives the drive command signal P transmitted from the command logic unit 22 to the delay controller 44, then transmits the command signal S after elapse of a delay of tdoff, sets the first PMOSFET 42 to off from this point on while setting the first NMOSFET 46 to on to turn off the first gate electrode Gs, and turns off the semiconductor switching element. As in the operation in the first embodiment, the voltage VGcE of the second gate electrode Gc can be thereby controlled to be equal to or higher than 0 V and equal to or lower than +VP/3.

### [Modified Example of Semiconductor Switching Element]

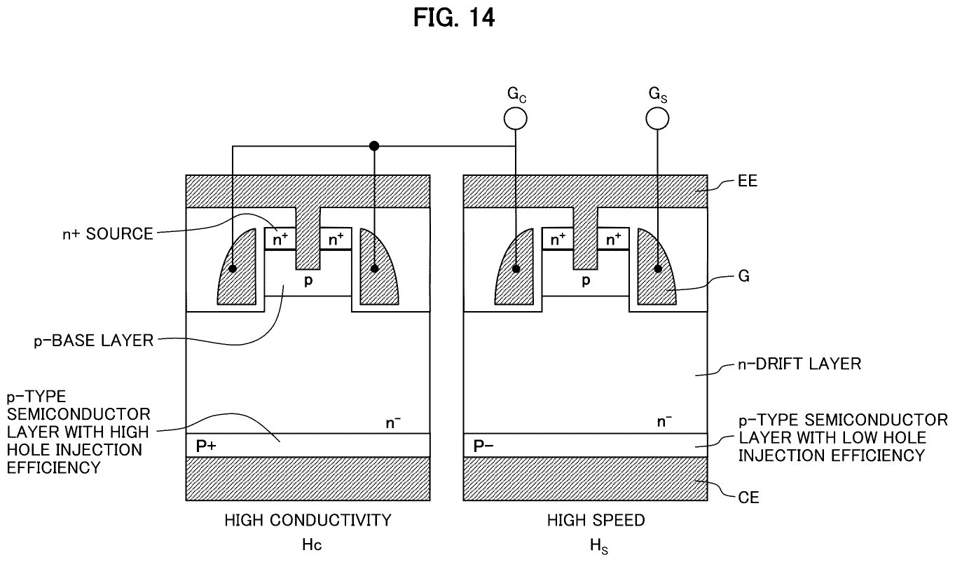

FIG. 14 is a diagram showing an example (modified example 1) of the semiconductor switching element. The semiconductor switching element of FIG. 14 is configured such that collector electrodes CE of a first chip Hc that is a chip with high hole injection efficiency from the collector side and a second chip Hs that is a chip with low hole injection efficiency from the collector side are connected in parallel to each other and emitter electrodes EE of the first chip Hc and the second chip Hs are connected in parallel to each other.

The second gate electrode Gc is connected to a gate of the first chip Hc, and both of the first gate electrode Gs and the second gate electrode Gc are connected to a gate of the second chip Hs.

Configuring the first chip HC with high conductivity and low conduction loss and the second chip Hs with high speed and low switching loss in a spatially divided manner has the following advantage. When this configuration is combined with the drive provided with the delay (tdoff) between the turning-off of the second gate electrode Gc and the turning-off of the first gate electrode Gs by the gate drive device 40 of the present embodiment, the effect of reducing the loss generated in the semiconductor switching element is further improved.

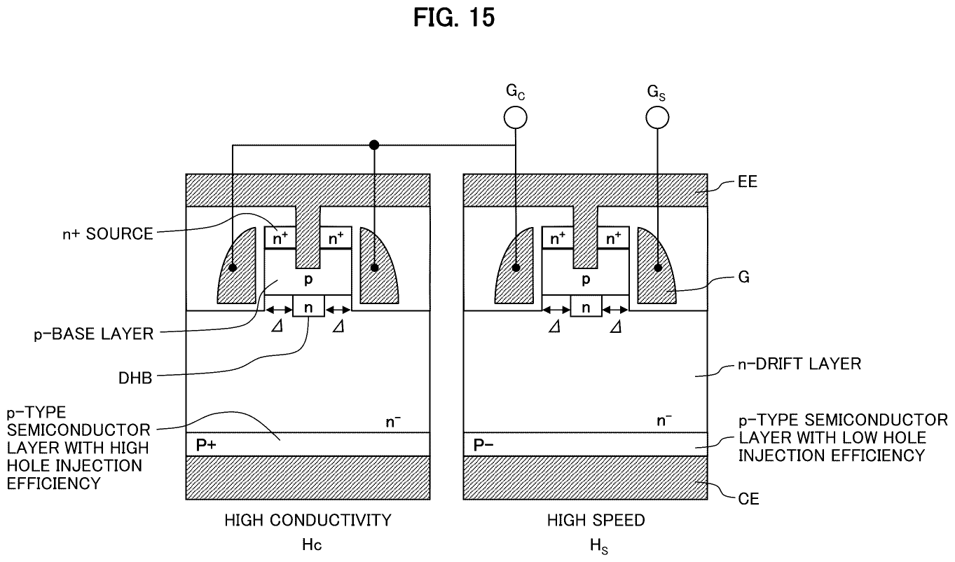

FIG. 15 is a diagram showing an example (modified example 2) of the semiconductor switching element. The semiconductor switching element of FIG. 15 is provided with a n-type semiconductor (DHB) with a higher impurity concentration than an n-drift layer, the n-type semiconductor provided below a p-base layer between the gates without coming into contact with the gates (corresponding to Δ in FIG. 15).

Providing the DHB with a higher impurity concentration than the n-drift layer increases an electric field intensity in a junction portion of the p-base layer and the DHB, and dynamic avalanche occurs in this location in the turn-off.

Since the DHB is provided away from the gates by the distance Δ without coming into contact with the gates, a region where the dynamic avalanche occurs is also located away from the gates. Accordingly, when this configuration is combined with the drive method of the present embodiment, the dynamic avalanche near the gates can be further suppressed, and the latch-up breakdown of the IGBT caused by the generate avalanche current is prevented. Specifically, there is an advantage of a further improvement of the IGBT breakdown withstanding capability.

[Delay (tdoff)]

The control of increasing the off time constant by using the off-side gate resistance Rgcoff (first embodiment) or the control of two-stage off (second embodiment) described above may be executed only when the first gate electrode Gs and the second gate electrode Gc are simultaneously turned off (for example, when the simultaneous off command signal (P′) is transmitted from the command logic unit 22 to the delay controller 44 and the turn-off is performed without delay tdoff=0).

### [Configuration Example of Inverter]

The semiconductor switching element is not limited to the IGBT, as long as the semiconductor switching element is a voltage drive type. The present disclosure can be applied also to the case where the semiconductor material is changed to Si, SiC, GaN, gallium oxide, or the like. The semiconductor switching element can be used not only in the electric power converter to be applied to a hybrid vehicle, an electric vehicle, and railway, but also in electric power converters in general.

The gate drive circuit for the semiconductor switching element, the electric motor control system, and the semiconductor device in the present embodiments explained above have the following characteristics.
(1) In the gate drive circuit for the semiconductor switching element whose drive is controlled by using two independent gate electrodes, the time constant of the gate electrode voltage in the turning-off of the second gate electrode Gc is set to be longer than that in the turning-off of the first gate electrode Gs, and the voltage V* of the second gate electrode at the time point at which the maximum power is applied in the turn-off of the semiconductor switching element satisfies Expression 1.

0≤V*≤predetermined value<+Vp Expression (1)

(+Vp in the expression is the gate drive voltage in the case where the semiconductor switching element is on)

According to this configuration, high breakdown withstanding capability of the semiconductor switching element can be achieved.
(2) In the gate drive circuit for the semiconductor switching element of (1), the time point at which the maximum power is applied in the turn-off of the semiconductor switching element is the time point at which the collector-emitter voltage (VCE) of the semiconductor switching element becomes substantially equal to the power supply voltage (for example, Vcc) in the turn-off.
(3) In the gate drive circuit for the semiconductor switching element of (1), the gate drive circuit includes the off-side gate resistance Rgcoff that controls the time constant in the turning-off of the second gate electrode Gc, and the off-side gate resistance Rgcoff is adjusted to control the voltage drop in the gate resistance. The off-side gate resistance Rgcoff may be manually adjusted by using a variable resistor, or for example, the variable resistor may be adjusted by using a command from the command logic unit 22.
(4) In the gate drive circuit for the semiconductor switching element whose drive is controlled by using two independent gate electrodes, the gate drive circuit is commanded to reduce the voltage of the first gate electrode to the negative-side power supply voltage (for example, −Vm) in the turning-off of the first gate electrode Gs, and is commanded to reduce the voltage of the second gate electrode Gc to the negative-side power supply voltage (for example, −Vm) in two stages in the turning-off of the second gate electrode Gc.
(5) In the gate drive circuit for the semiconductor switching element of (4), the gate drive circuit includes the power supply of the first voltage (for example, intermediate voltage 50), the gate switch (for example, third NMOSFET 51), and the switch controller 52, and the switch controller 52 first reduces the voltage (VGcE) of the second gate electrode to the first voltage (for example, power supply voltage=V**), and then after elapse of the predetermined time (At), reduces the voltage of the second gate electrode to the negative-side power supply voltage (for example, −Vm) of the gate drive circuit.
(6) In the gate drive circuit for the semiconductor switching element of any one of (1) to (5), the semiconductor switching element may be configured by connecting the collector electrodes of the first chip Hc that is a chip with high hole injection efficiency from the collector side and the second chip Hs that is a chip with low hole injection efficiency from the collector side in parallel to each other and by connecting the emitter electrodes of the first chip Hc and the second chip Hs in parallel to each other.
(7) In the gate drive circuit for the semiconductor switching element of (6), the second gate electrode Gc is connected to the gate of the first chip Hc, and both of the first gate electrode Gs and the second gate electrode Gc are connected to the gate of the second chip Hs.
(8) In the gate drive circuit for the semiconductor switching element of (6), the semiconductor switching element 31 is provided with the n-type semiconductor (DHB) with a higher impurity concentration than the n-drift layer, the n-type semiconductor provided below the p-base layer between the gates, without coming into contact with the gates.
(9) In the gate drive circuit for the semiconductor switching element of (1) or (4), the control is preferably performed when an off signal is simultaneously received for the first gate electrode Gs and the second gate electrode Gc.
(10) In the gate drive circuit for the semiconductor switching element of (1), the predetermined value is the threshold voltage Vth of the semiconductor switching element.
(11) In the gate drive circuit for the semiconductor switching element of (1), the predetermined value is +Vp/3.
(12) The electric motor control system 100 includes the semiconductor switching element 31 and the gate drive device 40 for each of the arms in the inverter circuit 20, the gate drive device 40 is the gate drive circuit for the semiconductor switching element of any one of (1) to (5), and the inverter circuit 20 outputs the AC current based on the DC power supplied from the DC power supply to the inverter circuit 20, and drives the electric motor 70.
(13) The electric motor control system 100 includes the semiconductor switching element 31 and the gate drive device 40 for each of the arms in the inverter circuit 20, the gate drive device 40 is the gate drive circuit for the semiconductor switching element of (6), and the inverter circuit 20 outputs the AC current based on the DC power supplied from the DC power supply to the inverter circuit 20, and drives the electric motor 70.
(14) The semiconductor device includes the semiconductor switching element 31 whose drive is controlled by using the two independent gate electrodes and the gate drive circuit for the semiconductor switching element of any one of (1) to (5).
(15) The semiconductor device includes the semiconductor switching element 31 whose drive is controlled by using the two independent gate electrodes and the gate drive circuit for the semiconductor switching element of (6).

### REFERENCE SIGNS LIST

10 DC power supply
20 inverter circuit
21 smoothing capacitor
22 command logic unit
23 positive electrode connection line
24 negative electrode connection line
30 inverter unit
31 semiconductor switching element
32 free-wheeling diode
33 connection point
40, 40A gate drive device (gate drive circuit)
41 positive-side power supply
42 first PMOSFET
43 second PMOSFET
44 delay controller
45 negative-side power supply
46 first NMOSFET
47 second NMOSFET
50 intermediate power supply (power supply of first voltage)
51 third NMOSFET (gate switch)
52 switch controller
70 electric motor
100 electric motor control system
Gs first gate electrode
Gc second gate electrode
Hc first chip
Hs second chip
Rgcon, Rgson on-side gate resistance
Rgcoff, Rgsoff off-side gate resistance (gate resistance)
Vth threshold voltage
VCE collector-emitter voltage
Vcc power supply voltage
TGs, TτGc time constant

1. A gate drive circuit for a semiconductor switching element whose drive is controlled by using two independent gate electrodes, wherein
a time constant of a gate electrode voltage in turning-off of a second gate electrode is set to be longer than that in turning-off of a first gate electrode, and
a voltage V* of the second gate electrode at a time point at which maximum power is applied in turn-off of the semiconductor switching element satisfies Expression (1):
0≤V*≤predetermined value<+Vp Expression (1):
(+Vp in the expression is a gate drive voltage in a the case where the semiconductor switching element is on).

2. The gate drive circuit for the semiconductor switching element according to claim 1, wherein
the time point at which the maximum power is applied in the turn-off of the semiconductor switching element is a time point at which a collector-emitter voltage of the semiconductor switching element becomes substantially equal to a power supply voltage in the turn-off.

3. The gate drive circuit for the semiconductor switching element according to claim 1, wherein
the gate drive circuit includes a gate resistance that controls the time constant in the turning-off of the second gate electrode, and the gate resistance is adjusted to control voltage drop in the gate resistance.

4. A gate drive circuit for a semiconductor switching element whose drive is controlled by using two independent gate electrodes, wherein
the gate drive circuit is commanded to reduce a voltage of a first gate electrode to a negative-side power supply voltage in turning-off of the first gate electrode, and is commanded to reduce a voltage of a second gate electrode to the negative-side power supply voltage in two stages in turning-off of the second gate electrode.

5. The gate drive circuit for the semiconductor switching element according to claim 4, wherein
the gate drive circuit includes a power supply of a first voltage, a gate switch, and a switch controller, and
the switch controller first reduces the voltage of the second gate electrode to the first voltage, and then after elapse of a predetermined time, reduces the voltage of the second gate electrode to the negative-side power supply voltage of the gate drive circuit.

6. The gate drive circuit for the semiconductor switching element according to claim 1, wherein
the semiconductor switching element is configured by connecting collector electrodes of a first chip that is a chip with high hole injection efficiency from a collector side and a second chip that is a chip with low hole injection efficiency from the collector side in parallel to each other and by connecting emitter electrodes of the first chip and the second chip in parallel to each other.

7. The gate drive circuit for the semiconductor switching element according to claim 6, wherein
the second gate electrode is connected to a gate of the first chip, and both of the first gate electrode and the second gate electrode are connected to a gate of the second chip.

8. The gate drive circuit for the semiconductor switching element according to claim 6, wherein
the semiconductor switching element is provided with an n-type semiconductor with a higher impurity concentration than an n-drift layer, the n-type semiconductor provided below a p-base layer between gates, without coming into contact with the gates.

9. The gate drive circuit for the semiconductor switching element according to claim 1, wherein
control is performed when an off signal is simultaneously received for the first gate electrode and the second gate electrode.

10. The gate drive circuit for the semiconductor switching element according to claim 1, wherein
the predetermined value is a threshold voltage of the semiconductor switching element.

11. The gate drive circuit for the semiconductor switching element according to claim 1, wherein
the predetermined value is +Vp/3.

12. An electric motor control system comprising a semiconductor switching element and a gate drive device for each of arms in an inverter circuit, wherein
the gate drive device is the gate drive circuit for the semiconductor switching element according to claim 1, and
the inverter circuit outputs an AC current based on a DC power supplied from a DC power supply to the inverter circuit, and drives an electric motor.

13. An electric motor control system comprising a semiconductor switching element and a gate drive device for each of arms in an inverter circuit, wherein
the gate drive device is the gate drive circuit for the semiconductor switching element according to claim 4, and
the inverter circuit outputs an AC current based on a DC power supplied from a DC power supply to the inverter circuit, and drives an electric motor.

14. A semiconductor device comprising:
a semiconductor switching element whose drive is controlled by using two independent gate electrodes; and
the gate drive circuit for the semiconductor switching element according to claim 1.

15. A semiconductor device comprising:
a semiconductor switching element whose drive is controlled by using two independent gate electrodes; and
the gate drive circuit for the semiconductor switching element according to claim 6.
